(19) United States
(12) Patent Application Publication
(10) Pub. No.: US 2025/0383688 A1
(43) Pub. Date: Dec. 18, 2025

(54) DISPLAY DEVICE AND ELECTRONIC APPARATUS

(71) Applicant: Samsung Display Co., Ltd., Yongin-si (KR)

(72) Inventors: JOOYOUNG KIM, Yongin-si (KR); YOUNG-JOO NAM, Yongin-si (KR); DOHYUN PARK, Yongin-si (KR); YOUNGJIN PARK, Yongin-si (KR)

(21) Appl. No.: 19/202,733

(22) Filed: May 8, 2025

(30) Foreign Application Priority Data
Jun. 17, 2024 (KR) 10-2024-0078155

(51) Int. Cl. G06F 1/16; H05K 1/18

(52) U.S. Cl. CPC G06F 1/1662; G06F 1/1656; G06F 1/1681; H05K 1/189; H05K 2201/10128

(57) ABSTRACT

An electronic apparatus includes a display device to display an image, and an input device unit to output a signal to the display device. The display device includes a display panel including a circuit element layer and defining a display region and a non-display region adjacent to the display region, a printed circuit board including an electronic component, and a flexible circuit board between the display panel and the printed circuit board and electrically connecting the display panel to the printed circuit board, and wherein at least two recessed portions are defined in one side surface of the circuit element layer.

### CROSS-REFERENCE TO RELATED APPLICATION

The present application claims priority to and the benefit of Korean Patent Application No. 10-2024-0078155, filed on Jun. 17, 2024, in the Korean Intellectual Property Office, the entire disclosure of which is incorporated herein by reference.

### BACKGROUND

### 1. Field

Embodiments of the present disclosure relate to a display device and an electronic apparatus, and for example, to a display device including a display panel with a reduced bezel and improved rigidity, and an electronic apparatus including the display device.

### 2. Description of the Related Art

Display devices, which provide an image to a user, such as televisions, monitors, smartphones, laptop computers, and tablet PCs, include a display panel which displays an image. Various display panels such as liquid crystal display panels, organic light-emitting display panels, electrowetting display panels, and electrophoretic display panels are being developed. Research into reducing the size of a bezel of a display panel and improving the rigidity of the display panel during the manufacturing process of the display panel is being conducted.

The above information disclosed in this Background section is intended to enhance understanding of the background of the disclosure and may contain information that does not constitute prior art.

### SUMMARY

The Aspects of one or more embodiments of the present disclosure are directed to a display device including a display panel with a reduced bezel and improved rigidity, and an electronic apparatus including the same.

Additional aspects will be set forth in part in the description which follows and, in part, will be apparent from the description, or may be learned by practice of the presented embodiments of the disclosure.

One or more embodiments of the present disclosure provide an electronic apparatus including a display device to display an image, and an input device unit to input a signal to the display device, wherein the display device includes a display panel including a circuit element layer and defining a display region and a non-display region adjacent to the display region, a printed circuit board including an electronic component, and a flexible circuit board arranged between the display panel and the printed circuit board and electrically connecting the display panel to the printed circuit board, and wherein at least two recessed portions are defined in one side surface of the circuit element layer.

In one or more embodiments, the one side surface of the circuit element layer and an end of the printed circuit board adjacent to the at least two recessed portions may be aligned in a plan view.

In one or more embodiments, the electronic apparatus may further include a hinge member connecting the display device to the input device unit, and the hinge member may overlap the at least two recessed portions.

In one or more embodiments, the display device may further include a cover panel arranged under the circuit element layer.

In one or more embodiments, the printed circuit board may overlap the non-display region and may be arranged on a rear surface of the display panel.

In one or more embodiments, the printed circuit board may overlap the display region and the non-display region, and may be arranged on a rear surface of the display panel.

In one or more embodiments, the at least two recessed portions may include a first recessed portion, a second recessed portion, and a third recessed portion which are spaced and/or apart (e.g., spaced apart or separated) from each other in a first direction, the circuit element layer may include a first protruding portion and a second protruding portion which protrude in a second direction crossing the first direction, and the first protruding portion may be arranged between the first recessed portion and the second recessed portion and the second protruding portion may be arranged between the second recessed portion and the third recessed portion.

In one or more embodiments, the display panel may further include an encapsulation layer arranged on the circuit element layer, an end of the encapsulation layer may protrude (extend) in the second direction from a boundary between the display region and the non-display region by a first length, an end of the circuit element layer may extend in the second direction from the end of the encapsulation layer by a second length, and the first protruding portion of the circuit element layer may protrude in the second direction from the end of the circuit element layer by a third length.

In one or more embodiments, the third length may be about 0.1 mm to about 2.62 mm.

In one or more embodiments, the printed circuit board may extend in the second direction from the end of the circuit element layer at the first recessed portion by a length of about 0.1 mm to about 3.92 mm.

In one or more embodiments, the printed circuit board may overlap the first recessed portion, the second recessed portion, and the third recessed portion of the circuit element layer, and an end of the printed circuit board may be aligned with an end of the first protruding portion in a plan view.

In one or more embodiments, an end of the first protruding portion of the circuit element layer may overlap the printed circuit board on a plane (e.g., in a plan view), and an end of the printed circuit board adjacent to the first protruding portion may overlap the flexible circuit board on a plane (e.g., in a plan view).

In one or more embodiments, on a plane (e.g., in a plan view), the flexible circuit board may protrude (extend) in the second direction from an end of the first protruding portion by a fourth length, a portion of the printed circuit board overlapping the first recessed portion may extend in the second direction by a sum of the third length and the fourth length, a portion of the printed circuit board overlapping the flexible circuit board may extend in the second direction from the end of the first protruding portion by a fifth length, and the fifth length may be smaller than the fourth length.

In one or more embodiments, the display device may further include a cover panel arranged under the circuit element layer, and the printed circuit board may overlap a portion of the cover panel.

In one or more embodiments, the at least two recessed portions may include a first recessed portion and a second recessed portion, and the circuit element layer may include a protruding portion arranged between the first recessed portion and the second recessed portion.

In one or more embodiments of the present disclosure, a display device includes a cover panel, a display panel having a circuit element layer arranged on the cover panel, a printed circuit board arranged on a rear surface of the display panel, and a flexible circuit board bent and electrically connecting the display panel to the printed circuit board, wherein the circuit element layer includes one or more protruding portions spaced and/or apart (e.g., spaced apart or separated) from each other in a first direction, and protruding in a second direction crossing the first direction, and the flexible circuit board connects the one or more protruding portions to the printed circuit board.

In one or more embodiments, the printed circuit board may be aligned with an end of the circuit element layer in a thickness direction of the circuit element layer.

In one or more embodiments, the printed circuit board may extend in the second direction from an end of the circuit element layer adjacent to the one or more protruding portions, and an end of the printed circuit board may overlap the flexible circuit board.

In one or more embodiments, the printed circuit board may extend in the second direction from an end of the circuit element layer adjacent to the one or more protruding portions, and an end of the printed circuit board may be aligned with a line extending from an end of the flexible circuit board on a plane (e.g., in a plan view).

In one or more embodiments, the circuit element layer may define a first recessed portion and a second recessed portion, which are adjacent to a protruding portion of the one or more protruding portions, and the protruding portion may be arranged between the first recessed portion and the second recessed portion.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a perspective view of an electronic apparatus according to one or more embodiments of the present disclosure;

FIG. 2 is an exploded perspective view of a display device according to one or more embodiments of the present disclosure;

FIG. 3 is a perspective view of a display module according to one or more embodiments of the present disclosure;

FIG. 4 is a cross-sectional view of a display module according to one or more embodiments of the present disclosure;

FIG. 5A is a plan view of a display module according to one or more embodiments of the present disclosure;

FIG. 5B is an enlarged view of region AA′ of FIG. 5A, which shows a portion of a display module according to one or more embodiments of the present disclosure;

FIG. 6 is a rear view of a display module according to one or more embodiments of the present disclosure;

FIG. 7 is a rear view of a display module according to one or more embodiments of the present disclosure;

FIG. 8A is a plan view of a display module according to one or more embodiments of the present disclosure;

FIG. 8B is a rear view of a display module according to one or more embodiments of the present disclosure;

FIG. 9A is a plan view of a display module according to one or more embodiments of the present disclosure;

FIG. 9B is a rear view of a display module according to one or more embodiments of the present disclosure;

FIG. 10A is a plan view of a display module according to one or more embodiments of the present disclosure;

FIG. 10B is a rear view of a display module according to one or more embodiments of the present disclosure;

FIG. 11 is a rear view of a display module according to one or more embodiments of the present disclosure; and

FIG. 12 is a plan view illustrating a display module according to one or more embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

It will be understood that when an element, such as an area, layer, film, region or portion, is referred to as being “on,” “connected to,” or “coupled to” another element, it can be directly on, connected to, or coupled to the other element, or one or more intervening elements may be present. In contrast, when an element or layer is referred to as being “directly on,” “directly connected to”, “directly coupled to”, or “immediately adjacent to” another element or layer, there are no intervening elements or layers present. In addition, it will also be understood that when an element is referred to as being “between” two elements, it can be the only element between the two elements, or one or more intervening elements may also be present.

Unless otherwise noted, like reference numerals denote like elements throughout the attached drawings and the written description, and thus, duplicative descriptions thereof may not be provided. In the drawings, the relative sizes, dimensions, thicknesses and/or ratios of elements, layers, and regions may be exaggerated for clarity. As used herein, the term “and/or” includes any and all combinations of one or more of the associated listed items.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

As used herein, the singular forms “a,” “an” and “the” are intended to include the plural forms as well, unless the context clearly indicates otherwise.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As used herein, the terms “use,” “using,” and “used” may be considered synonymous with the terms “utilize,” “utilizing,” and “utilized,” respectively.

In the context of the present disclosure and unless otherwise defined, a plan view is an orthographic projection of a three-dimensional object from the position of a horizontal plane through the object. That is, it is a top-down view, showing the layout and spatial relationships of various elements within the object or structure. A plan view based on the direction DR3 refers to a top-down view of the display panel, as if looking directly down onto the surface from above. In this context, DR3 is the direction perpendicular or normal to the plane defined by the first direction (DR1) and the second direction (DR2). This refers to that in a plan view, the arrangement of sub-pixels, pads, and other components as they are laid out on the substrate can be seen, without any perspective distortion.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the specification, and should not be interpreted in an idealized or overly formal sense, unless expressly so defined herein.

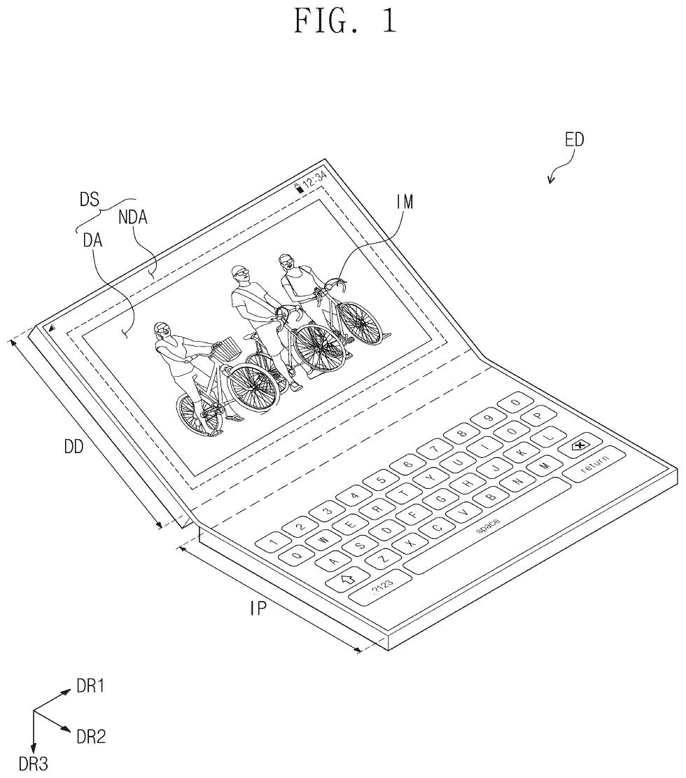

FIG. 1 is a perspective view of an electronic apparatus ED according to one or more embodiments of the present disclosure.

Referring to FIG. 1, the electronic apparatus ED may include a display device DD which displays an image IM, and an input device unit IP which receives an input and then outputs a signal to the display device DD based on the input. The electronic apparatus ED may be used in a state of being folded at a set or predetermined angle. The electronic apparatus ED may be used in a form of a laptop computer. When the electronic apparatus ED is folded, a hinge structure may be used.

The display device DD of the electronic apparatus ED may provide the image IM to a user through a display surface DS. The display surface DS of the display device DD may include a display region DA and a non-display region NDA around the display region DA. The display region DA may display the image IM, and the non-display region NDA may not display the image IM. The non-display region NDA may be around (e.g., surround) the display region DA. However, the present disclosure is not limited thereto, and a shape of the display region DA and a shape of the non-display region NDA may be modified.

The input device unit IP may be a keyboard of a laptop computer. An input signal of the keyboard arranged in the input device unit IP may be subjected to signal processing. The signal delivered from the input device unit IP may be transmitted to the display device DD of the electronic apparatus ED. In other words, the input device unit IP may receive an input (e.g., from a user typing on a keyboard), the input may undergo signal processing to convert it to a signal capable of being used by the display device DD (e.g., to display the words typed).

The display device DD may provide the display surface DS which is parallel to each of a first direction DR1 and a second direction DR2, and displays the image IM in a direction opposite to a third direction DR3. The display surface DS on which the image IM is displayed may correspond to a front surface of the display device DD.

A normal direction of the display surface DS, that is, a direction in which the image IM is displayed, may indicate a direction opposite to the third direction DR3. A front surface (or top surface) and a rear surface (or bottom surface) of each layer or unit to be described in more detail below may be distinguished based on the third direction DR3. However, first to third directions DR1, DR2, and DR3 illustrated are a relative concept and may thus be changed to other directions. Hereinafter, first to third directions may be defined as the directions respectively indicated by the first to third directions DR1, DR2, and DR3, and may thus be denoted as the same reference numerals or symbols. In this specification, the wording “on a plane (e.g., in a plan view)” may refer to “when viewed in the third direction DR3”.

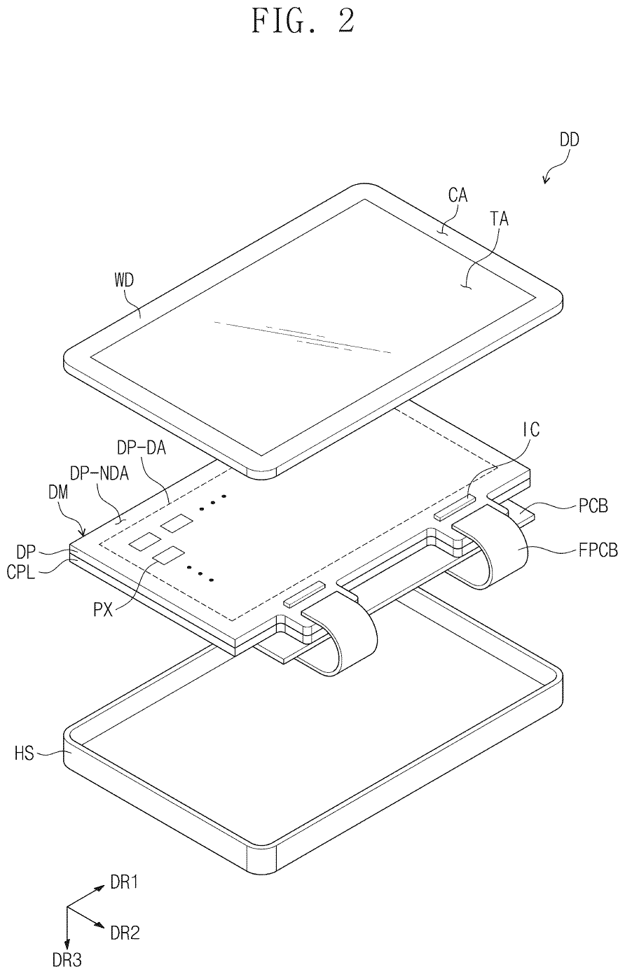

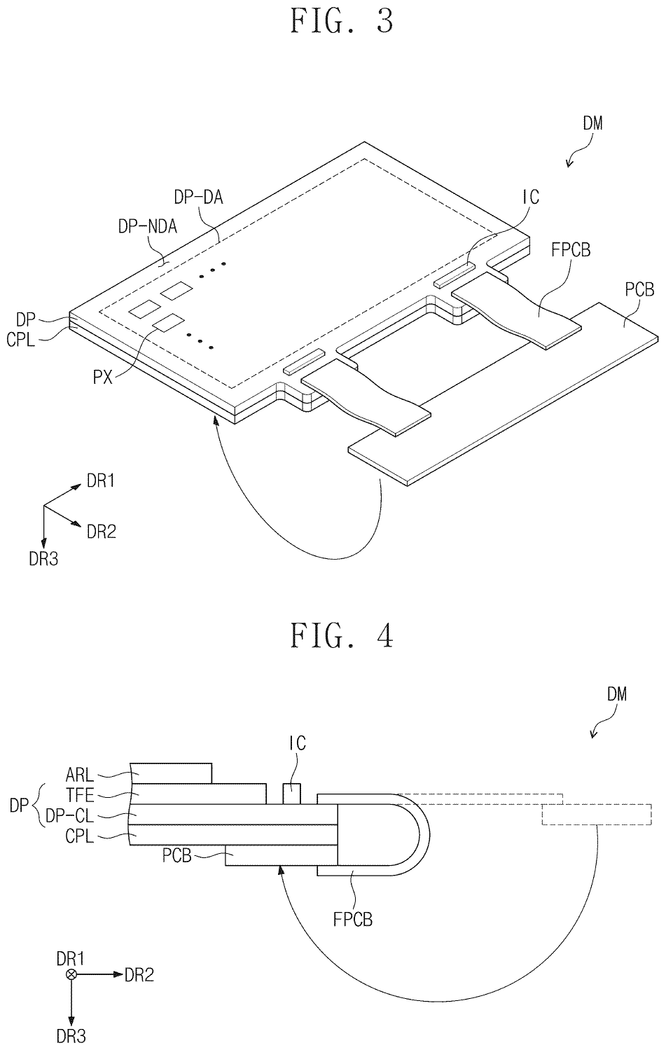

FIG. 2 is an exploded perspective view of a display device DD according to one or more embodiments of the present disclosure. FIG. 3 is a perspective view of a display module DM according to one or more embodiments of the present disclosure. FIG. 4 is a cross-sectional view of a display module DM according to one or more embodiments of the present disclosure. FIGS. 2 and 3 illustrate only some components for convenience of explanation.

Referring to FIGS. 2 to 4, the display device DD according to one or more embodiments of the present disclosure may have a rectangular shape including long sides extending in a first direction DR1 and short sides extending in a second direction DR2 normal (e.g., perpendicular) to the first direction DR1. This is an example for convenience of explanation, and a shape of the display device DD is not limited thereto and the display device may have one or more suitable shapes. For example, the display device DD may have a circular shape, a polygonal shape, or an atypical shape.

The display device DD may include a window member WD, a display module DM, and a housing HS. The display module DM and the window member WD may be coupled to each other by an adhesive layer. The adhesive layer may be a pressure sensitive adhesive (PSA) film or an optically clear adhesive (OCA) member.

The window member WD may define a light-transmitting region TA which transmits the image IM (see, e.g., FIG. 1) provided from the display module DM and a light-blocking region CA which is adjacent to the light-transmitting region TA and in which the image is not transmitted. The light-transmitting region TA of the window member WD may correspond to a display region DA of the display device DD, and the light-blocking region CA of the window member WD may correspond to a non-display region NDA of the display device DD.

The light-transmitting region TA may be defined in a central portion of the display device DD on a plane defined by the first direction DR1 and the second direction DR2 (e.g., in a plan view). The light-transmitting region TA may be a region in which the image IM is transmitted. A user may view the image IM through the light-transmitting region TA.

The light-blocking region CA may be defined at the periphery of the light-transmitting region TA and may have a frame shape around (e.g., surrounding) the light-transmitting region TA. The light-blocking region CA may have a set or predetermined color. A shape of the light-transmitting region TA may be defined substantially by the light-blocking region CA. However, the present disclosure is not limited thereto, and only the light-transmitting region TA may be defined in the window member WD and the light-blocking region CA may not be provided. For example, the image IM may be transmitted through the entire top surface of the display device DD.

The display module DM may be arranged under the window member WD. According to such embodiments, the display module DM may include a display panel DP, a printed circuit board PCB, a driving element IC, a flexible circuit board FP CB, a cover panel CPL, and an anti-reflection layer ARL (see, e.g., FIG. 4).

The display panel DP according to one or more embodiments of the present disclosure may be an organic electroluminescence display panel. However, the present disclosure is not particularly limited to type (kind) of the display panel DP. For example, the display panel DP may be a liquid crystal display panel, an electrophoretic display panel, a microelectromechanical system (MEMS) display panel, an electrowetting display panel, an inorganic light-emitting display panel, a nano-crystal display panel, or a quantum dot light-emitting display panel.

A display region DP-DA and a non-display region DP-NDA adjacent to the display region DP-DA may be defined in the display panel DP. The display region DP-DA may correspond to the light-transmitting region TA of the window member WD. The display region DP-DA may display the image IM. For example, the display panel DP may include pixels PX which are arranged on the display region DP-DA and in which light for generating images is displayed. The pixels PX may be arranged in a matrix form within the display region DP-DA. The pixels PX may have a Pentile (PENTILE®) (for example, an RGBG matrix, an RGBG structure, or RGBG matrix structure) arrangement form, a stripe arrangement form, or a diamond (DIAMOND PIXEL®) (e.g., a display (e.g., an OLED display) containing red, blue, and green (RGB) light emitting regions arranged in the shape of diamonds) arrangement form as well as the matrix form. PENTILE® and Diamond Pixel® are both duly registered trademarks of Samsung Display Co., Ltd.

The pixels PX may each include a pixel driving circuit composed of a light-emitting element, a plurality of transistors (for example, a switching transistor, a driving transistor, and/or the like) connected to the light-emitting element, and a capacitor. The pixels PX may each emit light in response to an electrical signal applied to the pixel PX. In FIG. 3, it is illustrated that the pixels PX are arranged in the display region DP-DA, but some of the components of the pixels PX may include a thin-film transistor arranged in the non-display region DP-NDA. The present disclosure is not limited to any one or more embodiments.

The non-display region DP-NDA may have a frame shape around (e.g., surrounding) the display region DP-DA. The non-display region DP-NDA may correspond to the light-blocking region CA of the window member WD.

The display panel DP may include a circuit element layer DP-CL and an encapsulation layer TFE. The circuit element layer DP-CL may be arranged on the cover panel CPL to be described in more detail later. The circuit element layer DP-CL may include at least one insulation layer and a circuit element. The insulation layer may include at least one inorganic layer and at least one organic layer. The circuit element may include signal lines, a pixel driving circuit, a thin-film transistor, and/or the like. The thin-film transistor may be divided into an amorphous silicon (a-Si) transistor, a low temperature poly silicon (LTPS) transistor, and/or the like, depending on the material. The circuit element layer DP-CL according to one or more embodiments of the present disclosure may include a low temperature poly silicon (LTPS) transistor, but other thin-film transistors may be included as long as they are capable of adjusting the brightness of the pixels PX.

The encapsulation layer TFE may seal the circuit element layer DP-CL. For example, the encapsulation layer TFE may include a thin-film encapsulation layer. The thin-film encapsulation layer may include a stacked structure of inorganic layer/organic layer/inorganic layer. The encapsulation layer TFE may protect the circuit element layer DP-CL from moisture, oxygen, and/or foreign materials, such as dust particles. However, the present disclosure is not limited thereto, and the encapsulation layer TFE may include an additional insulation layer other than the thin-film encapsulation layer. For example, an optical insulation layer for controlling a refractive index may further be included.

The printed circuit board PCB may include an electronic component. The printed circuit board PCB may be arranged on a rear surface of the display panel DP if (e.g., when) the printed circuit board PCB is electrically connected to the flexible circuit board FPCB and the flexible circuit board FPCB is bent.

The driving element IC may be mounted on the non-display region DP-NDA of the display panel DP. The driving element IC may output driving signals and image signals which are necessary for displaying an image. The driving element IC may serve to drive the display module DM. The driving element IC may be mounted on the display panel DP. As long as the driving element IC is capable of generating and controlling an output signal for operation of the display panel DP, the driving element may be mounted on a film in which a thin-film printed circuit is formed, and may also be mounted on the printed circuit board PCB.

The flexible circuit board FPCB may be arranged between the display panel DP and the printed circuit board PCB. The flexible circuit board FP CB may be bent. The flexible circuit board FPCB may electrically connect the display panel DP to the printed circuit board PCB. The flexible circuit board FPCB may be to transmit a signal from the printed circuit board PCB to the driving element IC, and transmit a signal to the display panel DP. For example, one end of the flexible circuit board FPCB may be connected to the display module DM, and the other end thereof may be connected to the printed circuit board PCB. At least a portion of the flexible circuit board FP CB may have a bending property. The flexible circuit board FPCB may include a bendable shape, so that the circuit element layer DP-CL may be arranged inside the bendable shape (e.g., the curve) of the flexible circuit board FPCB if (e.g., when) the circuit element layer DP-CL extends in the second direction DR2. In FIG. 3, it is illustrated that two flexible circuit boards FPCB are arranged, but the number of the flexible circuit boards FPCB may be one, or may be three or more.

The flexible circuit board FPCB may be arranged extending from the non-display region DP-NDA of the display panel DP. However, this is an example, and the flexible circuit board FP CB may not be provided in one or more embodiments of the present disclosure. In such embodiments, the printed circuit board PCB may be directly arranged on the extended display panel DP. The display panel DP in which the printed circuit board PCB is arranged may be bendable, and the printed circuit board PCB may be arranged on the rear surface of the display panel DP.

The cover panel CPL may be arranged under the circuit element layer DP-CL. The cover panel may be placed under the display panel DP and serve as a functional layer which is used to protect the display panel DP from an impact, and/or the like, delivered from below. The cover panel may be composed of a foam sheet and/or an elastic material, which may provide more protection to the display panel DP from an impact if (e.g., when) used in combination with polyimide (PI) and/or polyethylene terephthalate (PET). Some layers of the cover panel CPL may have a black color to prevent or reduce the likelihood of components under the cover panel CPL from being viewed.

The anti-reflection layer ARL may be arranged on the display panel DP. The anti-reflection layer ARL may reduce an external light reflectance. In one or more embodiments, the anti-reflection layer ARL may be a layer which selectively transmits light emitted from the display panel DP.

The housing HS (see, e.g., FIG. 2) may be arranged at a lowermost part of the display device DD, and may be coupled to the window member WD to accommodate the display module DM, the printed circuit board PCB, and the flexible circuit board FPCB therein. The housing HS may include plastic or metal. In one or more embodiments, the housing HS may not be provided.

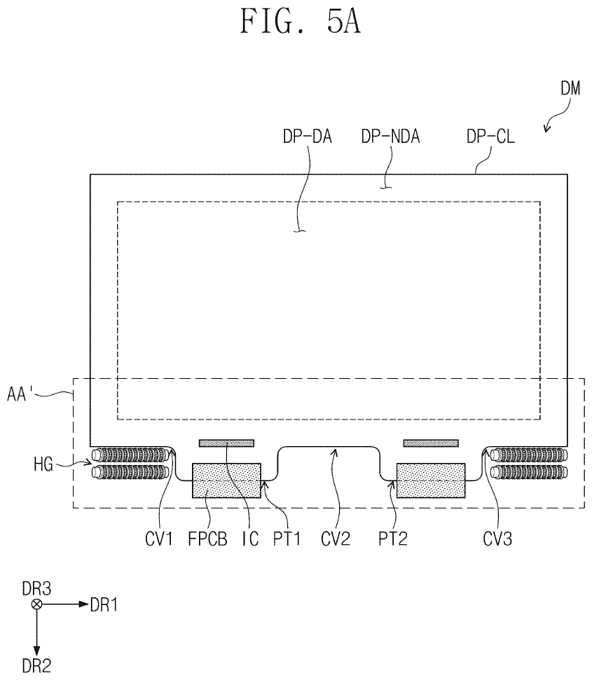

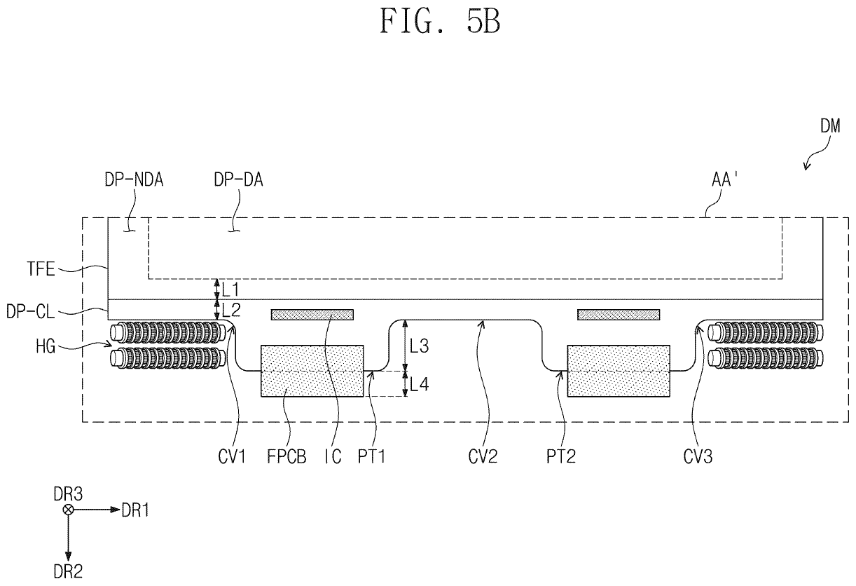

FIG. 5A is a plan view of a display module DM according to one or more embodiments of the present disclosure. FIG. 5B is an enlarged view of a portion of the display module DM according to one or more embodiments of the present disclosure. FIG. 5B is an enlargement of and illustrates a region corresponding to the region AA′ in FIG. 5A. In the explanation of FIGS. 5A and 5B, the description will be made with reference to FIGS. 1 to 4, and any description of the same reference numerals or symbols may not be provided in order to avoid redundancy.

Referring to FIGS. 5A and 5B, an encapsulation layer TFE may be arranged overlapping a display region DP-DA and a non-display region DP-NDA. An end of the encapsulation layer TFE may protrude (extend) in a second direction DR2 by a first length L1 from a boundary between the display region DP-DA and the non-display region DP-NDA. The end of the encapsulation layer TFE may be spaced and/or apart (e.g., spaced apart or separated) from an end of a circuit element layer DP-CL. For example, the end of the encapsulation layer TFE may be spaced and/or apart (e.g., spaced apart or separated) from the end of the circuit element layer DP-CL in a direction opposite to the second direction DR2.

At least two recessed portions CV1, CV2, and CV3 may be defined in one side surface of the circuit element layer DP-CL. The at least two recessed portions CV1, CV2, and CV3 may include a first recessed portion CV1, a second recessed portion CV2, and a third recessed portion CV3 which are spaced and/or apart (e.g., spaced apart or separated) from each other in a first direction DR1. The first recessed portion CV1, the second recessed portion CV2, and the third recessed portion CV3 may be formed by processing the circuit element layer DP-CL.

In one or more embodiments of the present disclosure, the circuit element layer DP-CL may include low temperature poly silicon (LTPS). However, this is an example, and the circuit element layer DP-CL may include another thin-film transistor other than the low temperature poly silicon (LTPS) as long as the at least two recessed portions CV1, CV2, and CV3 are formed by processing the circuit element layer DP-CL.

On a plane (e.g., in a plan view), the encapsulation layer TFE may not overlap at least two of the recessed portions CV1, CV2, and CV3. The first length L1 may be about 2.83 mm to about 5.45 mm. When the first length L1 of the encapsulation layer TFE is more than about 5.45 mm, the non-display region DP-NDA (or bezel region) of the display panel DP may increase. When the first length L1 of the encapsulation layer TFE is less than about 2.83 mm, the circuit element layer DP-CL may not be protected from moisture, oxygen, and/or foreign materials, such as dust particles.

The end of the circuit element layer DP-CL may extend in the second direction DR2 by a second length L2 from the end of the encapsulation layer TFE. For example, a length between the end of the circuit element layer DP-CL at the first recessed portion CV1 and the end of the encapsulation layer TFE may be the second length L2. The second length L2 may be a distance between the end of the circuit element layer DP-CL at the second recessed portion CV2 and the encapsulation layer TFE, may be a distance between the end of the circuit element layer DP-CL at the third recessed portion CV3 and the encapsulation layer TFE, and may also be a distance between the end of the circuit element layer DP-CL at the first recessed portion CV1 and the encapsulation layer TFE.

The circuit element layer DP-CL may include protruding portions PT1 and PT2. The protruding portions PT1 and PT2 may be spaced and/or apart (e.g., spaced apart or separated) from each other in the first direction DR1, and may protrude (or extend) in the second direction DR2 crossing the first direction DR1. For example, the circuit element layer DP-CL may include a first protruding portion PT1 and a second protruding portion PT2. The number of the protruding portions PT1 and PT2 may be one or more. The first protruding portion PT1 and the second protruding portion PT2 may be spaced and/or apart (e.g., spaced apart or separated) from each other in the first direction DR1, and the first protruding portion PT1 and the second protruding portion PT2 may protrude in the second direction DR2.

The first protruding portion PT1 may be arranged between the first recessed portion CV1 and the second recessed portion CV2, and the second protruding portion PT2 may be arranged between the second recessed portion CV2 and the third recessed portion CV3. For example, in the one side surface of the circuit element layer DP-CL, the first recessed portion CV1, the first protruding portion PT1, the second recessed portion CV2, the second protruding portion PT2, and the third recessed portion CV3 may be sequentially arranged along the first direction DR1.

A length of the first protruding portion PT1 which protrudes in the second direction DR2 and a length of the second protruding portion PT2 which protrudes in the second direction DR2 may be substantially the same. The first protruding portion PT1 and the second protruding portion PT2 may be formed during the process of forming the recessed portions CV1, CV2, and CV3 by processing the circuit element layer DP-CL. The first protruding portion PT1 of the circuit element layer DP-CL may protrude in the second direction DR2 by a third length L3 from the end of the circuit element layer DP-CL at the first recessed portion CV1. For example, the first recessed portion CV1 may be depressed from an end of the first protruding portion PT1 by the third length L3. The length of the first protruding portion PT1 which protrudes in the second direction DR2 may be substantially the same as the length of the second protruding portion PT2 which protrudes in the second direction DR2.

The third length L3 may be about 0.1 mm to about 2.62 mm. When the third length L3 is more than about 2.62 mm, the encapsulation layer TFE may be processed together with the circuit element layer DP-CL. When the encapsulation layer TFE is processed, the circuit element layer DP-CL may not be protected from moisture, oxygen, and/or foreign materials.

A flexible circuit board FPCB may connect a printed circuit board PCB to the protruding portions PT1 and PT2 formed in the circuit element layer DP-CL. The flexible circuit board FP CB may be connected to the circuit element layer DP-CL, and may be connected to the protruding portions PT1 and PT2. For example, the flexible circuit board FPCB may include the flexible circuit board FP CB connected to the first protruding portion PT1 and/or the flexible circuit board FP CB connected to the second protruding portion PT2. Here, the flexible circuit board FPCB may be connected to the first protruding portion PT1 and/or the second protruding portion PT2 to receive an electrical signal from the printed circuit board PCB and to transmit the electrical signal to the display panel DP.

An electronic apparatus ED may further include a hinge member HG connecting the display device DD (see, e.g., FIG. 1) to the input device unit IP (see, e.g., FIG. 1). The display device DD and the input device unit IP may be folded through the hinge member HG.

The hinge member HG may be adjacent to the display panel DP and arranged in the first recessed portion CV1 and the third recessed portion CV3. FIGS. 5A and 5B illustrate that the hinge member HG includes a spring structure, but the present disclosure is not limited thereto. The hinge member HG may include a hinge structure, a gear structure, and/or the like, other than a spring structure, as long as the hinge member HG connects the display device DD to the input device unit IP.

The hinge member HG may overlap at least two of the recessed portions CV1, CV2, and CV3 of the display panel DP. For example, the hinge member HG may be arranged overlapping the first recessed portion CV1 and the third recessed portion CV3. For example, due to the recessed portions CV1, CV2, and CV3, the hinge member HG may be arranged closer to the center of the display panel DP from an end of the display panel DP (or the circuit element layer DP-CL), than the case where the recessed portions CV1, CV2, and CV3 are not defined. In other words, due to the hinge members HG being within the recessed portions CV1, CV2, and CV3, the hinge members HG are closer to the display panel DP (e.g., closer to the center of the display panel DP) than the hinge members HG would be if the recessed portions CV1, CV2, and CV3 were not there. The recessed portions CV1, CV2, and CV3 may be depressed from the end of the first protruding portion PT1 by the third length L3, and the hinge member HG may be arranged adjacent to (closer to) the center of the display panel DP by the third length L3 from the end of the circuit element layer DP-CL. As a result, a region (or bezel region) in which the hinge member HG is arranged may be reduced or removed.

A length from the end of the first protruding portion PT1 to a point, which is farthest away from a bending axis of the flexible circuit board FPCB in the second direction DR2, may be defined as a fourth length L4. On a plane (e.g., in a plan view), the fourth length L4 may be a length by which the flexible circuit board FP CB protrudes farthest away from the end of the first protruding portion PT1 in the second direction DR2. In other words, the flexible circuit board FPCB may have one end attached to the display panel DP and then may curve under the display panel DP to attach to the printed circuit board PCB. The point of the flexible circuit board FPCB that is the farthest away in a second direction DR2 is the point along the curve of the flexible circuit board FPCB between the display panel DP and the printed circuit board PCB at which the bend in the flexible circuit board FP CB is farthest away in a second direction DR2 from the display panel DP and the printed circuit board PCB. The fourth length L4 may be a length measured from the end of the first protruding portion PT1 to the part of the flexible circuit board FPCB that is farthest from the first protruding portion PT1 in the second direction DR2.

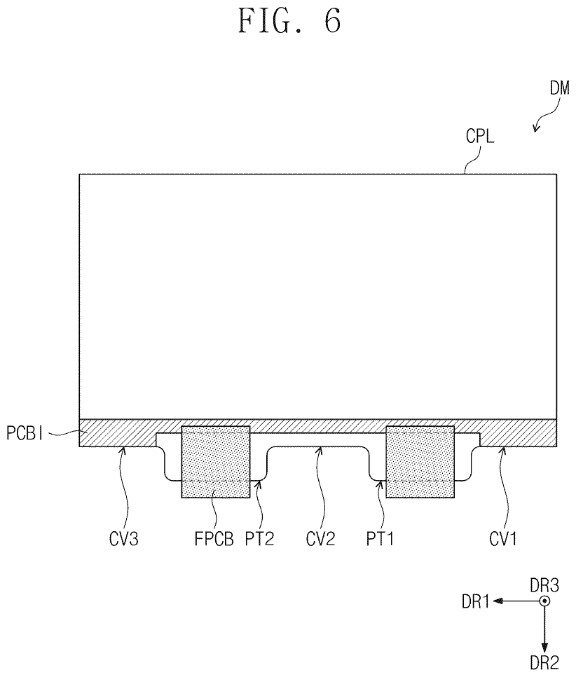

FIG. 6 is a rear view of a display module DM according to one or more embodiments of the present disclosure. In the explanation of FIG. 6, the description will be made with reference to FIGS. 1 to 5B, and any description of the same reference numerals or symbols may not be provided in order to avoid redundancy.

Referring to FIGS. 5A and 6, a printed circuit board PCBI may overlap a non-display region DP-NDA and may be arranged on a rear surface of a display panel DP. The printed circuit board PCBI may be arranged on a rear surface of a cover panel CPL. It is illustrated that the printed circuit board PCBI is arranged overlapping the non-display region DP-NDA of the display panel DP. However, the printed circuit board PCBI may overlap a display region DP-DA and the non-display region DP-NDA and may be arranged on the rear surface of the display panel DP as long as a flexible circuit board FPCB is connected to the printed circuit board PCBI and able to transmit an electrical signal to the display panel DP.

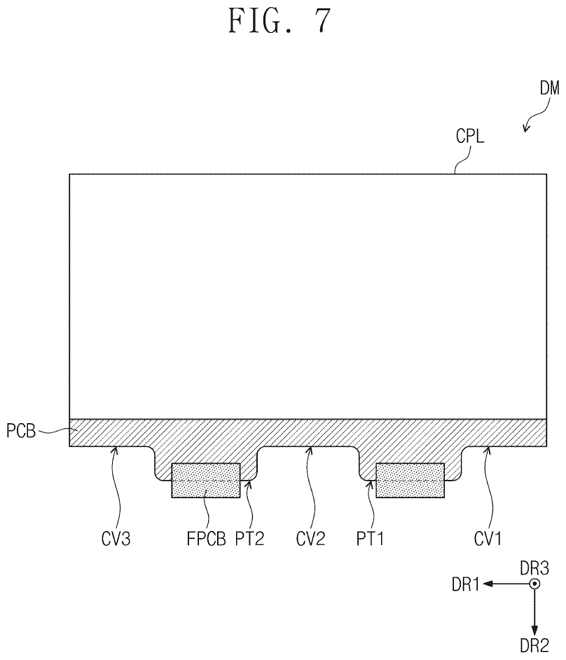

The printed circuit board PCBI may have one or more suitable shapes. An opening overlapping protruding portions PT1 and PT2 may be defined in the printed circuit board PCBI, as shown in FIG. 6. The opening may overlap the flexible circuit board FPCB. On a cross section, an end of the printed circuit board PCBI may not be aligned with a portion of an end of a circuit element layer DP-CL at recessed portions CV1, CV2, and CV3. For example, on a cross section, the end of the printed circuit board PCBI may be aligned with the end of the circuit element layer DP-CL at a first recessed portion CV1 and/or a third recessed portion CV3, and may not be aligned with the end of the circuit element layer DP-CL at a second recessed portion CV2. However, this is an example, and on a cross section, the end of the printed circuit board PCBI may be aligned with the ends of the circuit element layer DP-CL which define the recessed portions CV1, CV2, and CV3. Various shapes of the printed circuit board PCB will be described in more detail with reference to FIGS. 7 to 11 below.

FIG. 7 is a rear view of a display module DM according to one or more embodiments of the present disclosure. In the explanation of FIG. 7, the description will be made with reference to FIGS. 1 to 6, and any description of the same reference numerals or symbols may not be provided in order to avoid redundancy.

Referring to FIGS. 5A and 7, an end of a circuit element layer DP-CL in which at least two recessed portions CV1, CV2, and CV3 are defined and an end of a printed circuit board PCB adjacent to at least two of the recessed portions CV1, CV2, and CV3 may be aligned on a cross section. The end of the printed circuit board PCB, which is adjacent to the end of the circuit element layer DP-CL defining the recessed portions CV1, CV2, and CV3, may be arranged along the end of the circuit element layer DP-CL. In one or more embodiments, the printed circuit board PCB may be arranged along the end of the circuit element layer DP-CL at a first protruding portion PT1 and a second protruding portion PT2. For example, the end of the printed circuit board PCB and the end of the circuit element layer DP-CL may be aligned in a thickness direction of the circuit element layer DP-CL. The printed circuit board PCB may have a shape corresponding to a shape of one side (a side surface in which the recessed portions CV1, CV2, and CV3 and protruding portions PT1 and PT2 are defined) of the circuit element layer DP-CL on a rear surface of a cover panel CPL.

The rigidity of one side surface of the circuit element layer DP-CL, which is processed in a process of forming the recessed portions CV1, CV2, and CV3 of the circuit element layer DP-CL may be reduced after the processing. Cracks may occur in the one side surface of the processed circuit element layer DP-CL, due to the reduced rigidity. In one or more embodiments of the present disclosure, the printed circuit board PCB may be positioned on a rear surface of the circuit element layer DP-CL to correspond to the shape of the one side (the side surface in which the recessed portions CV1, CV2, and CV3 are defined) of the circuit element layer DP-CL, and the display module DM including the circuit element layer DP-CL and the printed circuit board PCB corresponding thereto becomes thicker, thereby improving impact resistance. Thus, it is possible to reduce or prevent cracks that would occur in the circuit element layer DP-CL if (e.g., when) an impact is applied to the protruding portion (or recessed portion) of the circuit element layer DP-CL.

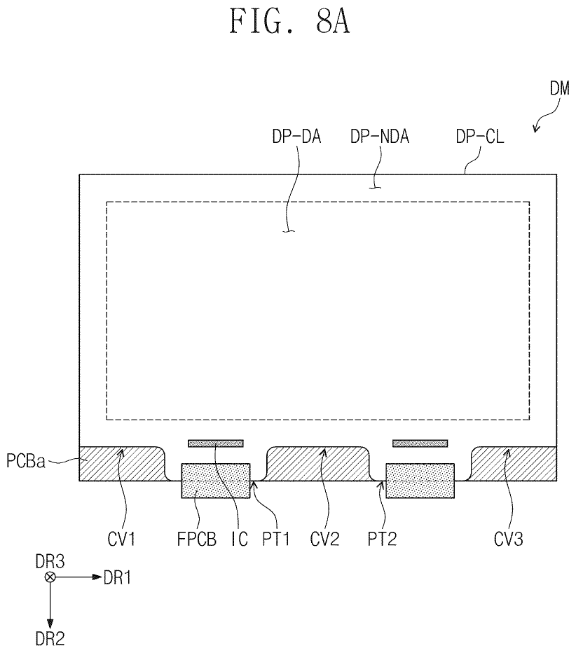

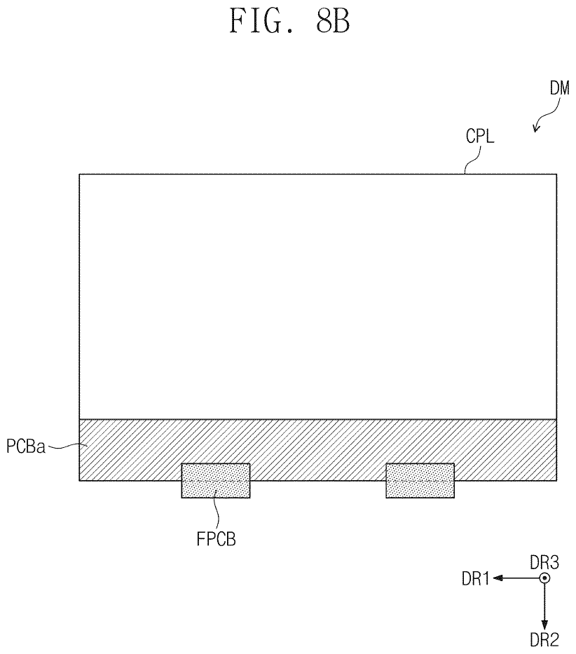

FIG. 8A is a plan view of a display module DM according to one or more embodiments of the present disclosure. FIG. 8B is a rear view of the display module DM according to one or more embodiments of the present disclosure. In the explanation of FIGS. 8A and 8B, the description will be made with reference to FIGS. 1 to 7, and any description of the same reference numerals or symbols may not be provided in order to avoid redundancy.

Referring to FIGS. 8A and 8B, a printed circuit board PCBa may be arranged on a rear surface of a display panel DP and may extend in a second direction DR2 from an end of a circuit element layer DP-CL at a first recessed portion CV1. The printed circuit board PCBa may overlap the first recessed portion CV1, a second recessed portion CV2, and a third recessed portion CV3 of the circuit element layer DP-CL. A length by which the printed circuit board PCBa extends in the second direction DR2 from an end of the circuit element layer DP-CL at the first recessed portion CV1, a length by which the printed circuit board PCBa extends in the second direction DR2 from an end of the circuit element layer DP-CL at the second recessed portion CV2, and a length by which the printed circuit board PCBa extends in the second direction DR2 from an end of the circuit element layer DP-CL at the third recessed portion CV3 may be substantially the same. An end of the printed circuit board PCBa may be aligned with an end of a first protruding portion PT1 on a cross section. For example, the length by which the printed circuit board PCBa extends in the second direction DR2 from the end of the circuit element layer DP-CL in which the first recessed portion CV1 is defined and a length by which the first protruding portion PT1 extends in the second direction DR2 from an extending line of the end of the circuit element layer DP-CL in which the first recessed portion CV1 is defined may be substantially the same. In other words, the protruding portion PT1 and the printed circuit board PCBa may extend substantially the same distance (length) from the first recessed portion CV1 in the second direction DR2, so that the edges of the protruding portion PT1 and the printed circuit board PCBa are aligned.

FIGS. 8A and 8B illustrate that on a cross section, the printed circuit board PCBa extends in the second direction DR2 to be aligned with a line of the first protruding portion PT1, extending in a first direction DR1. However, this is an example, and an extending shape of the printed circuit board PCBa (e.g., the edge of the printed circuit board that extends in the second direction DR2 and is along the first direction DR1) is not limited to the above example as long as the printed circuit board PCBa may be to transmit electrical signals via a flexible circuit board FPCB, and increase the rigidity of the circuit element layer DP-CL including at least two of the recessed portions CV1, CV2, and CV3. For example, the length by which the printed circuit board PCBa extends in the second direction DR2 from the end of the circuit element layer DP-CL in which the first recessed portion CV1 is defined may be smaller than the length by which the first protruding portion PT1 extends in the second direction DR2 from the end of the circuit element layer DP-CL. A portion of the printed circuit board PCBa extending in the second direction DR2 may partially overlap at least two of the recessed portions CV1, CV2, and CV3.

One side surface of the circuit element layer DP-CL, which is processed in a process of forming at least two of the recessed portions CV1, CV2, and CV3 of the circuit element layer DP-CL may decrease in rigidity, and thus cracks may occur therein. Because the printed circuit board PCBa is positioned on a rear surface of the display panel DP, impact resistance may be further improved as the display module DM including the circuit element layer DP-CL and the printed circuit board PCBa corresponding thereto becomes thicker. Thus, it is possible to reduce or prevent cracks that would occur in the circuit element layer DP-CL if (e.g., when) an impact is applied to the protruding portion (or recessed portion) of the circuit element layer DP-CL.

In one or more embodiments, the printed circuit board PCBa may overlap the recessed portions CV1, CV2, and CV3 of the circuit element layer DP-CL due to the extended length of the printed circuit board PCBa in the second direction DR2. For example, the protruding portion(s) PT1 and/or PT2 and the printed circuit board PCBa may extend substantially the same distance (length) from any one or more of the recessed portions CV1, CV2 and/or CV3 in the second direction DR2, so that the edges of the protruding portion(s) PT1 and/or PT2 and the printed circuit board PCBa are aligned. When an impact is applied to portions where the recessed portions CV1, CV2, and CV3 overlap the printed circuit board PCBa, the printed circuit board PCBa may receive the impact first, and the impact transmitted to the circuit element layer DP-CL, in which the recessed portions CV1, CV2, and CV3 are defined, may be reduced or prevented.

An extending shape of the printed circuit board PCBa in the second direction DR2 may have a quadrangular shape. For example, the edge of the printed circuit board PCBa that extends in the second direction DR2 and is along the first direction DR1 may define part of the quadrangular shape of the printed circuit board PCBa. This is an example for convenience of explanation, and the extending shape of the printed circuit board PCBa is not particularly limited thereto and printed circuit board may have one or more suitable shapes. For example, the printed circuit board PCBa may have curvature or an atypical shape at the end thereof.

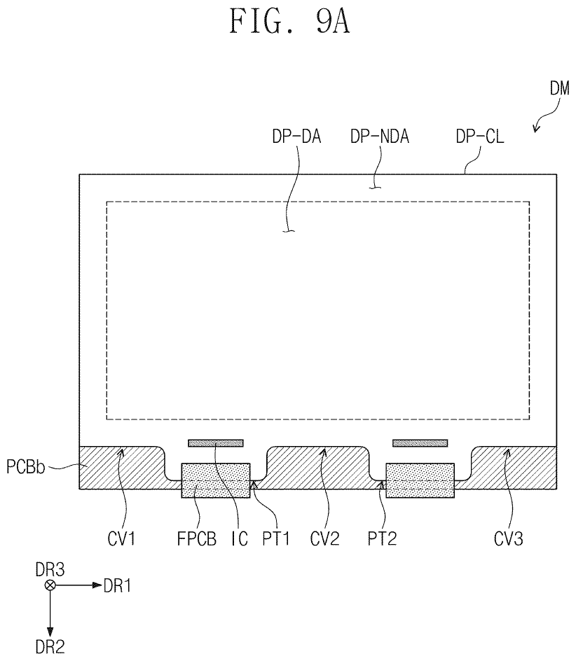

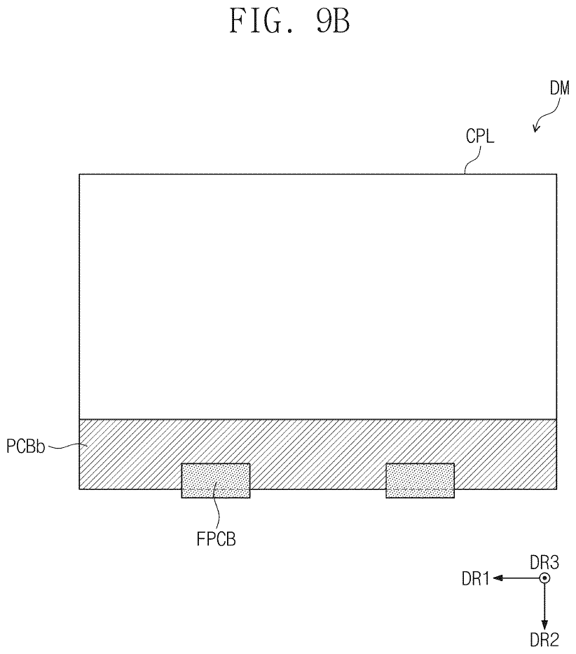

FIG. 9A is a plan view of a display module DM according to one or more embodiments of the present disclosure. FIG. 9B is a rear view of the display module DM according to one or more embodiments of the present disclosure. In the explanation of FIGS. 9A and 9B, the description will be made with reference to FIGS. 1 to 7, and any description of the same reference numerals or symbols may not be provided in order to avoid redundancy.

A printed circuit board PCBb may extend in a second direction DR2 from an end of a circuit element layer DP-CL at a first recessed portion CV1. The printed circuit board PCBb may extend in the second direction DR2 from the end of the circuit element layer DP-CL adjacent to protruding portions PT1 and PT2. The printed circuit board PCBb may extend in the second direction DR2, and may extend further than an end of a first protruding portion PT1 and an end of a second protruding portion PT2 in the second direction DR2.

The end of the first protruding portion PT1 of the circuit element layer DP-CL may overlap the printed circuit board PCBb on a plane (e.g., in a plan view), and an end of the printed circuit board PCBb adjacent to the first protruding portion PT1 may overlap a flexible circuit board FP CB on a plane (e.g., in a plan view).

The flexible circuit board FP CB may be arranged between the circuit element layer DP-CL and the printed circuit board PCBb, and the flexible circuit board FPCB may be bent. The flexible circuit board FPCB and the printed circuit board PCBb may be arranged overlapping the circuit element layer DP-CL on a plane (e.g., in a plan view). For example, the printed circuit board PCBb may be arranged between the bent structures (ends) of the flexible circuit board FP CB, and the end of the printed circuit board PCBb may overlap the flexible circuit board FPCB on a plane (e.g., in a plan view).

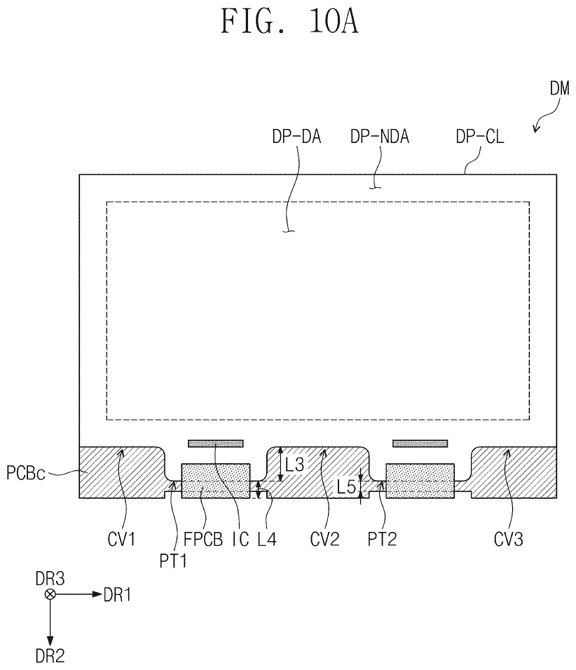

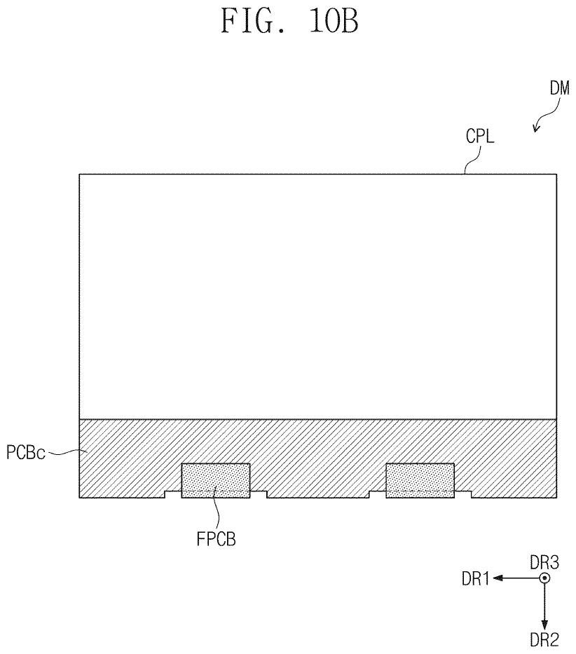

FIG. 10A is a plan view of a display module DM according to one or more embodiments of the present disclosure. FIG. 10B is a rear view of the display module DM according to one or more embodiments of the present disclosure. In the explanation of FIGS. 10A and 10B, the description will be made with reference to FIGS. 1 to 7, and any description of the same reference numerals or symbols may not be provided in order to avoid redundancy.

Referring to FIGS. 10A and 10B, a flexible circuit board FPCB may be bent with respect to a bending axis. A point at which the flexible circuit board FP CB is farthest away in a second direction DR2 on a plane (e.g., in a plan view) may be a point at which a bent portion of the flexible circuit board FPCB, among bent portions which are bent from the bending axis, is farthest away in the second direction DR2. In other words, the flexible circuit board FPCB may have one end attached to the display panel DP and then may curve under the display panel DP to attach to the printed circuit board PCBc. The point of the flexible circuit board FP CB that is the farthest away in a second direction DR2 is the point along the curve of the flexible circuit board FPCB between the display panel DP and the printed circuit board PCBc at which the bend in the flexible circuit board FPCB is farthest away in a second direction DR2 from the display panel DP and the printed circuit board PCBc. For example, on a plane (e.g., in a plan view), the flexible circuit board FP CB may protrude in the second direction DR2 by a fourth length L4 from an end of a first protruding portion PT1. A length by which the flexible circuit board FP CB protrudes in the second direction DR2 from the end of the first protruding portion PT1 and a length by which the flexible circuit board FP CB protrudes in the second direction DR2 from an end of a second protruding portion PT2 may be substantially the same. In other words, the fourth length L4 may be a length measured from the end of the first protruding portion PT1 and/or the second protruding portion PT2 to the part of the flexible circuit board FPCB that is farthest from the first protruding portion PT1 and/or the second protruding portion PT2, respectively, in the second direction DR2.

On a plane (e.g., in a plan view), the printed circuit board PCBc may be arranged on a rear surface of a display panel DP, and may extend in the second direction DR2. An end, extending in the second direction DR2, of a portion in which the printed circuit board PCBc overlaps a first recessed portion CV1 may, in a first direction DR1, be parallel to an end of the flexible circuit board FPCB protruding in the second direction DR2 and also extending in the first direction DR1. For example, on a plane (e.g., in a plan view), an end of the printed circuit board PCBc may be aligned with the end of the flexible circuit board FP CB extending in the first direction DR1. The end of the flexible circuit board FPCB may be arranged along a line extending in the first direction DR1 and that line may be aligned with the end of the printed circuit board PCBc. A portion of the printed circuit board PCBc, overlapping the first recessed portion CV1 may extend in the second direction DR2 from an end of the circuit element layer DP-CL by a sum of the third length L3 and the fourth length L4. A length by which the printed circuit board PCBc extends in the second direction DR2 from an end of the circuit element layer DP-CL at the first recessed portion CV1 may be substantially the same as a length by which the printed circuit board PCBc extends in the second direction DR2 from an end of the circuit element layer DP-CL at the second recessed portion CV2 and a length by which the printed circuit board PCBc extends in the second direction DR2 from an end of the circuit element layer DP-CL at the third recessed portion CV3.

The printed circuit board PCBc may extend in the second direction DR2 from an end of the circuit element layer DP-CL adjacent to the protruding portions PT1 and PT2. A portion of the printed circuit board PCBc overlapping the flexible circuit board FPCB may extend in the second direction DR2 by a fifth length L5 from the end of the first protruding portion PT1. The end of the printed circuit board PCBc may be arranged overlapping the flexible circuit board FPCB. The fifth length L5 may be smaller than the fourth length L4. For example, on a plane (e.g., in a plan view), the flexible circuit board FP CB may extend further along the second direction DR2 than the printed circuit board PCBc at the protruding portions PT1 and PT2.

In one or more embodiments, a difference between the fourth length L4 and the fifth length L5 may be substantially the same as a thickness of the flexible circuit board FPCB. For example, the length, that is, the fifth length L5, by which the printed circuit board PCBc extends in the second direction DR2 in a portion overlapping the flexible circuit board FP CB, may be a length, excluding (minus) the thickness of the flexible circuit board FP CB, from the protruding portion PT1 and/or PT2 to the point at which a bending shape (e.g., the curve) of the flexible circuit board FPCB is farthest away in the second direction DR2. However, this is an example in which the end of the printed circuit board PCBc overlapping the first protruding portion PT1 is in contact with the flexible circuit board FPCB, and the present disclosure is not limited thereto.

Referring to FIGS. 8A to 10B, the printed circuit boards PCBa, PCBb, and PCBc may be formed so as to correspond to the shape of the flexible circuit board FPCB. The ends of the printed circuit boards PCBa, PCBb, and PCBc may extend until coming into contact with the flexible circuit board FPCB. A length by which the printed circuit boards PCBa, PCBb, and PCBc extend in the second direction DR2 from the end of the circuit element layer DP-CL may be about 0.1 mm to about 3.92 mm. For example, if (e.g., when) the length by which the printed circuit boards PCBa, PCBb, and PCBc extend in the second direction DR2 from the end of the circuit element layer DP-CL is more than about 3.92 mm, shapes of the printed circuit boards PCBa, PCBb, and PCBc or a shape of the flexible circuit board FPCB may be deformed, and a non-display region DP-NDA (or bezel region) may increase so as to prevent or reduce the likelihood of deformation of the shapes of the printed circuit boards PCBa, PCBb, and PCBc and/or the flexible circuit board FPCB.

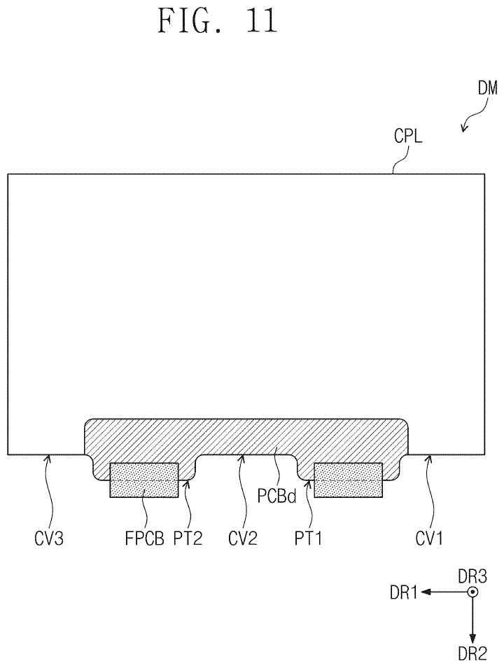

FIG. 11 is a rear view of a display module DM according to one or more embodiments of the present disclosure. In the explanation of FIG. 11, the description will be made with reference to FIGS. 1 to 7, and any description of the same reference numerals or symbols may not be provided in order to avoid redundancy.

Referring to FIG. 11, a display device DD may include a cover panel CPL arranged under a circuit element layer DP-CL. A printed circuit board PCBd may overlap a portion of the cover panel CPL. For example, the printed circuit board PCBd may overlap the cover panel CPL which is adjacent to a first protruding portion PT1, a second recessed portion CV2, and a second protruding portion PT2, and may not overlap the cover panel CPL which is adjacent to a first recessed portion CV1 and a third recessed portion CV3. A width of the printed circuit board PCBd in a first direction DR1 may be smaller than a width of the cover panel CPL in the first direction DR1. A boundary of the printed circuit board PCBd parallel to a second direction DR2 may be spaced and/or apart (e.g., spaced apart or separated) in a direction parallel to the first direction DR1 from a boundary of the cover panel CPL parallel to the second direction DR2.

A protection film may be arranged on the cover panel CPL. The cover panel CPL may be arranged under a display panel DP to protect the display panel DP from an impact delivered from below, and the protection film may be arranged on a lower surface of the cover panel CPL to reduce or prevent scratches which may occur on the cover panel CPL due to an external impact. Even after a manufacturing process of the display panel DP is completed, the protection film may be arranged under the portion of the cover panel CPL, which does not overlap the printed circuit board PCBd, to protect the cover panel CPL from an external impact.

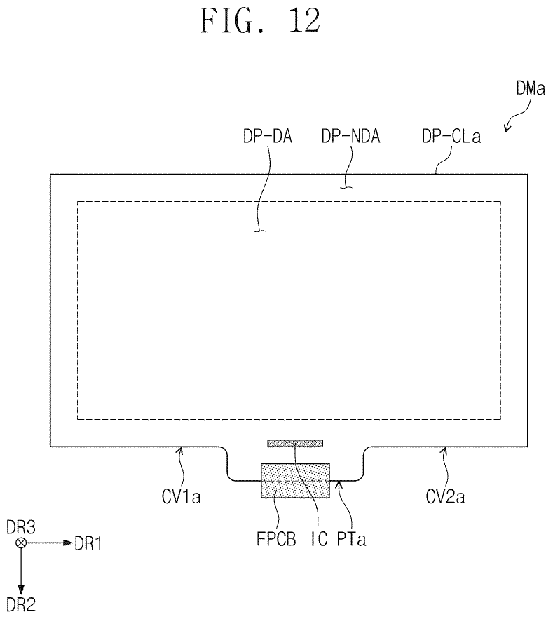

FIG. 12 is a plan view illustrating a display module DMa according to one or more embodiments of the present disclosure. In the explanation of FIG. 12, the description will be made with reference to FIGS. 1 to 7, and any description of the same reference numerals or symbols may not be provided in order to avoid redundancy.

Referring to FIG. 12, the display module DMa may include a display panel, and the display panel may include a circuit element layer DP-CLa and the encapsulation layer TFE (see, e.g., FIG. 4). At least two recessed portions CV1a and CV2a may be defined in the circuit element layer DP-CLa. The at least two recessed portions CV1a and CV2a may include a first recessed portion CV1a and a second recessed portion CV2a. The first recessed portion CV1a and the second recessed portion CV2a may be formed by processing one side of the circuit element layer DP-CLa. The first recessed portion CV1a and the second recessed portion CV2a may be spaced and/or apart (e.g., spaced apart or separated) from each other in a first direction DR1.

The circuit element layer DP-CLa may include a protruding portion PTa arranged between the first recessed portion CV1a and the second recessed portion CV2a. The protruding portion PTa may be adjacent to the first recessed portion CV1a and the second recessed portion CV2a. The protruding portion PTa may protrude (or extend) in a second direction DR2. The protruding portion PTa may be formed during a process of forming the recessed portions CV1a and CV2a by processing the circuit element layer DP-CLa. This is an example, and the protrusions of a flexible circuit board FP CB may be arranged in plurality. For example, the protruding portion PTa may be provided in plurality, and the number of the recessed portions CV1a and CV2a provided herein may also be three or more.

The flexible circuit board FP CB may connect the protruding portion PTa, which is formed in the circuit element layer DP-CLa, to the printed circuit board PCB (see, e.g., FIG. 7). The flexible circuit board FPCB may be connected to the circuit element layer DP-CLa, and connected to the protruding portion PTa. Here, the flexible circuit board FPCB may be connected to the protruding portion PTa to receive an electrical signal from the printed circuit board PCB and transmit the electrical signal to a display panel DP.

Description of the flexible circuit board FPCB and the protruding portions PT1 and PT2 of the circuit element layer DP-CL made with reference to FIGS. 5A to 11 may be similarly applied to the protruding portion PTa in FIG. 12. For example, first to fourth lengths L1, L2, L3, and L4 with respect to the circuit element layer DP-CLa and the protruding portion PTa may be defined as those described above, and may thus have the same ranges as described above.

For example, referring to FIGS. 5A to 12, the encapsulation layer TFE may protrude (extend) in the second direction DR2 by the first length L1 from a boundary between the display region DP-DA and the non-display region DP-NDA. The first length L1 may be about 2.83 mm to about 5.45 mm. When the first length L1 of the encapsulation layer TFE is more than about 5.45 mm, the non-display region DP-NDA (or bezel region) of the display panel DP may increase. When the first length L1 of the encapsulation layer TFE is less than about 2.83 mm, the circuit element layer DP-CLa may not be protected from moisture, oxygen, and/or foreign materials, such as dust particles.

An end of the circuit element layer DP-CLa may extend in the second direction DR2 by the second length L2 from an end of the encapsulation layer TFE. For example, a length between the end of the circuit element layer DP-CLa at the first recessed portion CV1a and the end of the encapsulation layer TFE may be the second length L2.

The protruding portion PTa of the circuit element layer DP-CLa may protrude in the second direction DR2 by the third length L3 from the end of the circuit element layer DP-CLa at the first recessed portion CV1a. The first recessed portion CV1a may be depressed from an end of the protruding portion P Ta by the third length L3. The third length L3 may be about 0.1 mm to about 2.62 mm. When the third length L3 is more than about 2.62 mm, the encapsulation layer TFE may be processed together with the circuit element layer DP-CLa. When the encapsulation layer TFE is processed, the circuit element layer DP-CLa may not be protected from moisture, oxygen, and/or foreign materials.

On a plane, the fourth length L4 may be a length by which the flexible circuit board FP CB protrudes farthest away from the end of the protruding portion PTa in the second direction DR2. In other words, the flexible circuit board FPCB may have one end attached to the display panel DP and then may curve under the display panel DP to attach to the printed circuit board PCB. The point of the flexible circuit board FP CB that is the farthest away in a second direction DR2 is the point along the curve of the flexible circuit board FP CB between the display panel DP and the printed circuit board PCB at which the bend in the flexible circuit board FPCB is farthest away in a second direction DR2 from the display panel DP and the printed circuit board PCB. The fourth length L4 may be a length measured from the end of the first protruding portion PTa to the part of the flexible circuit board FPCB that is farthest from the first protruding portion PTa in the second direction DR2. A sum of the third length L3 and the fourth length L4 may be about 3.92 mm or less. For example, if (e.g., when) a length by which the printed circuit board PCB extends in the second direction DR2 from the end of the circuit element layer DP-CLa is more than about 3.92 mm, a shape of the printed circuit board PCB or the flexible circuit board FPCB may be deformed, and the non-display region DP-NDA (or bezel region) may increase so as to prevent or reduce the likelihood of deformation of the shape of the printed circuit board PCBc and/or the flexible circuit board FPCB.

According to the above description, because recessed portions are defined in a circuit element layer according to embodiments of the present disclosure, a hinge member may be arranged adjacent to (or closer to) a center of a display panel. As a result, a region (non-display region, or bezel region) in which the hinge member is arranged may be reduced, decreased, or removed.

In one or more embodiments, a printed circuit board may be arranged on a rear surface of the circuit element layer to correspond to a shape of one side of the circuit element layer. As a display module including the circuit element layer and the printed circuit board corresponding thereto becomes thicker, cracks, which may occur in the circuit element layer if (e.g., when) an impact is applied to a protruding portion (or recessed portion) of the circuit element layer, may be reduced or prevented.

Further, the use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within +30%, 20%, 10%, 5% of the stated value.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The display device, electronic apparatus, device for manufacturing the display device, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. An electronic apparatus comprising:
a display device to display an image; and
an input device unit to output a signal to the display device,
wherein the display device comprises:
a display panel comprising a circuit element layer and defining a display region and a non-display region adjacent to the display region,
a printed circuit board comprising an electronic component, and
a flexible circuit board between the display panel and the printed circuit board and electrically connecting the display panel to the printed circuit board,
wherein at least two recessed portions are defined in one side surface of the circuit element layer.

2. The electronic apparatus of claim 1, wherein the one side surface of the circuit element layer and an end of the printed circuit board adjacent to the at least two recessed portions are aligned in a plan view.

3. The electronic apparatus of claim 1, further comprising a hinge member connecting the display device to the input device unit,
wherein the hinge member overlaps the at least two recessed portions.

4. The electronic apparatus of claim 1, wherein the display device further comprises a cover panel under the circuit element layer.

5. The electronic apparatus of claim 1, wherein the printed circuit board overlaps the non-display region and is on a rear surface of the display panel.

6. The electronic apparatus of claim 1, wherein the printed circuit board overlaps the display region and the non-display region, and is on a rear surface of the display panel.

7. The electronic apparatus of claim 1, wherein the at least two recessed portions comprise a first recessed portion, a second recessed portion, and a third recessed portion which are spaced from each other in a first direction,
the circuit element layer comprises a first protruding portion and a second protruding portion which protrude in a second direction crossing the first direction, and
the first protruding portion is between the first recessed portion and the second recessed portion, and the second protruding portion is between the second recessed portion and the third recessed portion.

8. The electronic apparatus of claim 7, wherein the display panel further comprises an encapsulation layer on the circuit element layer,
an end of the encapsulation layer extends in the second direction from a boundary between the display region and the non-display region by a first length,
an end of the circuit element layer extends in the second direction from the end of the encapsulation layer by a second length, and
the first protruding portion of the circuit element layer protrudes in the second direction from the end of the circuit element layer by a third length.

9. The electronic apparatus of claim 8, wherein the third length is about 0.1 mm to about 2.62 mm.

10. The electronic apparatus of claim 8, wherein the printed circuit board extends in the second direction from the end of the circuit element layer at the first recessed portion by a length of about 0.1 mm to about 3.92 mm.

11. The electronic apparatus of claim 7, wherein the printed circuit board overlaps the first recessed portion, the second recessed portion, and the third recessed portion of the circuit element layer, and an end of the printed circuit board is aligned with an end of the first protruding portion in a plan view.

12. The electronic apparatus of claim 7, wherein an end of the first protruding portion of the circuit element layer overlaps the printed circuit board in a plan view, and an end of the printed circuit board adjacent to the first protruding portion overlaps the flexible circuit board in the plan view.

13. The electronic apparatus of claim 8, wherein the flexible circuit board extends in the second direction from an end of the first protruding portion by a fourth length,
a portion of the printed circuit board overlapping the first recessed portion extends in the second direction by a sum of the third length and the fourth length,
a portion of the printed circuit board overlapping the flexible circuit board extends in the second direction from the end of the first protruding portion by a fifth length, and
the fifth length is smaller than the fourth length.

14. The electronic apparatus of claim 7, wherein the display device further comprises a cover panel under the circuit element layer, and
the printed circuit board overlaps a portion of the cover panel.

15. The electronic apparatus of claim 1, wherein the at least two recessed portions comprise a first recessed portion and a second recessed portion, and
the circuit element layer comprises a protruding portion between the first recessed portion and the second recessed portion.

16. A display device comprising:
a cover panel;
a display panel comprising a circuit element layer on the cover panel;
a printed circuit board on a rear surface of the display panel; and
a flexible circuit board bent and electrically connecting the display panel to the printed circuit board,
wherein the circuit element layer comprises one or more protruding portions spaced from each other in a first direction, and protruding in a second direction crossing the first direction, and
the flexible circuit board connects the one or more protruding portions to the printed circuit board.

17. The display device of claim 16, wherein the printed circuit board is aligned with an end of the circuit element layer in a thickness direction of the circuit element layer.

18. The display device of claim 16, wherein the printed circuit board extends in the second direction from an end of the circuit element layer adjacent to the one or more protruding portions, and an end of the printed circuit board overlaps the flexible circuit board.

19. The display device of claim 16, wherein the printed circuit board extends in the second direction from an end of the circuit element layer adjacent to the one or more protruding portions, and an end of the printed circuit board is aligned with a line extending along an end of the flexible circuit board in a plan view.

20. The display device of claim 16, wherein the circuit element layer defines a first recessed portion and a second recessed portion, which are adjacent to a protruding portion of the one or more protruding portions, and the protruding portion is between the first recessed portion and the second recessed portion.
